(19) United States
(12) Patent Application Publication
(10) Pub. No.: US 2026/0343938 A1
(43) Pub. Date: Oct. 29, 2026

(54) TRENCH MOSFET WITH THICKER BOTTOM GATE OXIDE

(71) Applicant: Microchip Technology Incorporated, Chandler, AZ (US)

(72) Inventors: Shesh Mani Pandey, Gilbert, AZ (US); George Dorman, Chandler, AZ (US)

(73) Assignee: Microchip Technology Incorporated, Chandler, AZ (US)

(21) Appl. No.: 19/188,833

(22) Filed: Apr. 24, 2025

Related U.S. Application Data
(60) Provisional application No. 63/682,261, filed on Aug. 12, 2024.

(51) Int. Cl. H10D 30/66; H10D 30/01; H10D 62/832; H10D 64/27

(52) U.S. Cl. CPC H10D 30/668; H10D 30/0297; H10D 62/8325; H10D 64/516

(57) ABSTRACT

A trench metal oxide semiconductor field-effect transistor includes a thicker bottom gate oxide. A volume of semiconductor material includes first and second ends. A source is located at a first end, and a drain is provided. A trench extends into the volume semiconductor material from the first end thereof. The trench is adjacent to the source and includes a trench bottom, a trench side extending between the trench bottom and the first end of the volume of semiconductor material, and trench a width. A gate oxide is located within the trench. The gate oxide includes a bottom layer that is adjacent the trench bottom and presents a bottom oxide layer average thickness, and a side layer that extends along the trench side and presents a side oxide layer average thickness. The bottom oxide layer average thickness is greater than the side oxide layer average thickness.

### RELATED APPLICATION

The present U.S. non-provisional patent application is related to and claims priority benefit of an earlier-filed U.S. provisional patent application titled "Trench MOSFET with Thicker Bottom Gate Oxide," Serial No. 63/682,261, filed Aug. 12, 2024. The entire content of the identified earlier-filed application is incorporated by reference as if fully set forth herein.

### FIELD

The present disclosure relates to metal oxide semiconductor field-effect transistors and methods of making them, and more particularly, the various examples described herein concern a trench metal oxide semiconductor field-effect transistor with a thicker bottom gate oxide, and a method of making a trench metal oxide semiconductor field-effect transistor with a thicker bottom gate oxide.

### BACKGROUND

A metal-oxide-semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide a trench MOSFET with a thicker bottom gate oxide, and a method of making a trench MOSFET with a thicker bottom gate oxide. Broadly, silicon (Si) is implanted into a semiconductor material at the bottom of the trench and then oxidized in place to provide a thicker gate oxide layer at the bottom. Examples advantageously provide improved performance, including improved ruggedness, with the desirable reverse conduction of silicon carbide (SiC) MOSFETs, and reduced cost.

In an example, a trench metal-oxide semiconductor field-effect transistor with a thicker bottom gate oxide may include a volume of semiconductor material, a source, a drain, a trench, and a gate oxide within the trench. The volume of semiconductor material may include a first end and a second end. The source may be located at the first end of the volume of semiconductor material. The trench may extend into the volume semiconductor material from the first end thereof. The trench may be adjacent to the source and may include a trench bottom, a trench side extending between the trench bottom and the first end of the volume of semiconductor material, and trench a width. The gate oxide may may include a bottom layer that is adjacent the trench bottom and presents a bottom oxide layer average thickness. The gate oxide may also include a side layer that extends along the trench side and presents a side oxide layer average thickness. The bottom oxide layer average thickness may be greater than the side oxide layer average thickness.

The preceding example may further include any one or more of the following features. The bottom layer of gate oxide may include silicon dioxide. The bottom oxide layer average thickness may be between one-and-two-tenths (1.2) and five (5) times greater than the side oxide layer average thickness. The bottom layer of gate oxide may be wider than the trench width. The drain being located at the second end of the volume of semiconductor material, such that a vertical channel is defined between the source and the drain. A gate material may be located within the trench. A well may underlie the source, and the well may have a lowermost margin spaced closer to the first end of the volume of semiconductor material than the trench bottom. The trench may include a pair of trench sides. The side layer of gate oxide may extend along each of the trench sides. The source may abut the side layer of gate oxide extending along each of the trench sides. The well may abut the side layer of gate oxide extending along each of the trench sides. The source may include an N+ material, the well may include a P material, the drain may include an N+ material, a drift portion of the volume of semiconductor material, which defines at least a portion of a channel extending between the source and drain, may include N material.

In another example, a method of making a trench FET with a thicker bottom gate oxide may include the operations set forth below. A source at a first end of a volume of semiconductor material may be provided. A trench may be etched into the volume of semiconductor material from the first end thereof, with the trench being adjacent to the source and including a trench bottom, a trench side extending between the trench bottom and the first end of the volume of semiconductor material, and a trench width. A bottom layer of silicon may be implanted into the volume of semiconductor material below the trench bottom. The bottom layer of silicon may be oxidized to form a bottom layer of silicon dioxide at the trench bottom. A side layer of silicon dioxide may be provided along the trench side. A gate material may be deposited into the trench to form a gate.

The preceding example may further include any one or more of the following features. The step of implanting the bottom layer of silicon may use an ion implanter to implant the silicon. The step of oxidizing the bottom layer of silicon may include thermally oxidizing the silicon. The steps of implanting and oxidizing the bottom layer of silicon and providing the side layer of silicon dioxide may be performed so that an average thickness of the bottom layer of silicon dioxide is between one-and-two-tenths (1.2) and five (5) times greater than an average thickness of the side layer of silicon dioxide. The step of implanting the bottom layer of silicon may be performed so that the bottom layer of silicon dioxide is wider than the trench width. The step of providing the side layer of silicon dioxide may include thermally oxidizing the trench side to form the side layer of silicon dioxide.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of an example of a trench MOSFET with a thicker bottom gate oxide;

FIG. 2 is a flowchart of operations in an example of a method of manufacturing a trench MOSFET with a thicker bottom gate oxide;

FIG. 3A is a cross-sectional elevation view of the result of an operation in the method of FIG. 2, wherein a partial MOSFET structure is shown before a trench is etched;

FIG. 3B is a cross-sectional elevation view of the result of an operation in the method of FIG. 2, wherein the trench has been etched;

FIG. 3C is a cross-sectional elevation view of the result of an operation in the method of FIG. 2, wherein silicon has been implanted into the bottom of the etched trench; and

FIG. 3D is a cross-sectional elevation view of the result of an operation in the method of FIG. 2, wherein the implanted silicon has been oxidized.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples. The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide a trench MOSFET with a thicker bottom gate oxide, and a method of making a trench MOSFET with a thicker bottom gate oxide. Broadly, silicon (Si) is implanted (using, e.g., an ion implanter) into the semiconductor material at the bottom of the trench and then oxidized in place (using, e.g., thermal oxidation) to provide a thicker silicon dioxide (SiO2) gate oxide layer. The average thickness of this layer of gate oxide (at the bottom of the trench) may be one-and-two-tenths (1.2) to five (5) times thicker than the average thickness of each of the layers of gate oxide at the sides of the trench. To be clear, the Si is implanted into the semiconductor material at the bottom of the trench and then oxidized to provide SiO2, rather than being directly deposited as SiO2 at the bottom of the trench. The region of gate oxide may be generally rectangular or oval in shape. The region of implanted Si may be wider than the bottom of the trench (i.e., it may extend laterally into the semiconductor material beyond the width of the trench), so that the bottom layer of gate oxide may be wider than the bottom of the trench. Examples result in improved performance, including improved ruggedness, with the desirable reverse conduction of SiC MOSFETs, and reduced cost. More specifically, a higher voltage on the drain can degrade the gate oxide at the bottom of the trench, so thicker gate oxide at that location advantageously allows for thinner and narrower shielding which results in a lower electrical resistance (Rds(on)) to electrical current flow through the channel between the drain and the source.

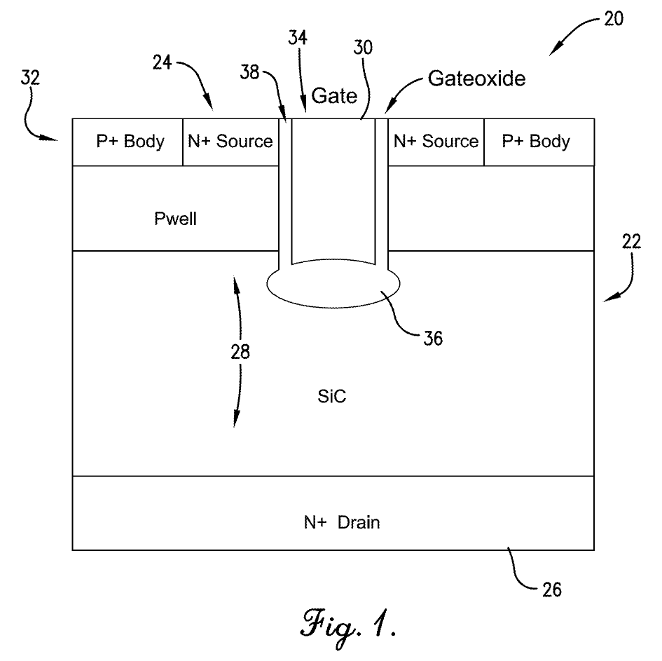

Referring to FIG. 1, an example of a trench MOSFET 20 with a thicker bottom gate oxide may include a volume of semiconductor material 22, source 24, a drain 26, a channel 28, a gate 30, a body 32, and a trench 34.

The volume of semiconductor material 22 may include a first end, a second, a left side, and a right side. The volume of semiconductor material 22 may include an N-type material. It will be appreciated that the sides of the illustrated volume of semiconductor material are defined herein merely as an example, and may in various examples represent only a portion of semiconductor material relative to the illustrated transistor 20. In practice, the volume of semiconductor may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be FETs (which may be similarly or alternatively constructed to the illustrated MOSFET 20) or may be entirely different devices providing different operations or functions than the illustrated MOSFET 20. In other words, in practice, the illustrated MOSFET 20 may be just one of numerous devices spaced laterally and transversely within a single, integrally formed array, such as a wafer (not shown).

The source 24 may be located at the first end of the volume of semiconductor material 22 and provide an entrance for charge carriers into the channel 28. The source 24 may include N+ material. The drain 26 may be located at the second end of the volume of semiconductor material 22, spaced apart from the source 24, and provide an exit for the charge carriers from the channel 28. The drain 26 may include N+ material. According to some aspects, the drain may alternatively be provided at the first end of the volume of semiconductor material to provide a lateral MOSFET configuration. The channel 28 may be a region of the semiconductor material 22 extending between the source 24 and the drain 26 and through which the charge carriers move, i.e., through which electrical current flows. The gate 30 may facilitate controlling the flow of charge carriers, and therefore the flow of electrical current through the channel 28. The gate 30 may include a polysilicon or other gate material. The body 32 may cooperate with the gate 30 to control current flow between the source 24 and the drain 26. The body 32 may include a P-type material. The body 32 may be electrically connected to the source 24 in order to eliminate a body bias that might otherwise affect the threshold voltage of the FET. In the illustrated example of a FET, the source 24 and body 32 each include left and right instances (i.e., a left source and a right source) located on opposite sides of the centrally-located trench 34, as shown. As needed or desired, the FET 20 may include additional structures, such as a P-well.

The trench 34 may be a cavity etched or otherwise created in the volume of semiconductor material 22 at the first end, between the left and right sides, and adjacent to the source 24. The trench 34 may include a trench bottom, a pair of spaced apart trench sides extending between the trench bottom and the first end, and a trench width. A mask 40 may be used to facilitate the etching process.

The source 24 may extend in an abutting relationship between each body 32 and a corresponding one of the trench sides. The well (which is preferably a P material) may underlie the source 24 and extend from and abut each trench side. Furthermore, the well may extend to the respective side of the volume of semiconductor material 22. It is further noted that the well depth may be tuned for the particular application, MOSFET 20 configuration, and/or material types. However, in the illustrated example, the well may include a lowermost margin that is spaced closer to the first end of the volume of semiconductor material 22 than the trench bottom.

A gate oxide may be located within the trench 34. A bottom layer 36 of gate oxide (e.g., SiO2) may be provided at the trench bottom, between the gate material and a drift region of the MOSFET 20. (The drift region may be the epitaxially grown portion of the volume of semiconductor material 22 defining the channel 28 below the well. It may be said that the reference number 28 also generally identifies the drift region. The drift region may be formed of N material.) The gate oxide may also include a side layer 38 of gate oxide (also, e.g., SiO2) provided along each trench side, between the gate material and each of the source 24 and the well. In the illustrated example, the side layer 38 of gate oxide is also defined between the gate material and a portion of the drift region, although this interface may be eliminated in some examples based upon the desired (tuned) depth of the well (as noted above). It is also noted that the bottom layer 36 of gate oxide presents a bottom oxide layer average thickness (the average being defined by averaging any thickness variations in the layer 36). The side layer 38 (along each trench side) may similarly present a side oxide layer average thickness (the average being defined by averaging any thickness variations in the layer 38). The bottom oxide layer average thickness is greater than the side oxide layer average thickness. In one example, the bottom oxide layer average thickness of gate oxide may be between one-and-two-tenths (1.2) and five (5) times thicker than the side oxide layer average thickness.

Achieving the thicker bottom layer 36 of gate oxide may be accomplished by implanting Si (using, e.g., an ion implanter) into the semiconductor material at the bottom of the trench 34, and then oxidizing the Si (using, e.g., thermal oxidation) in place to produce an initial layer of SiO2. It will be appreciated that implantation of Si actually places the Si implant below the trench bottom. The Si implant allows for achieving shapes and dimension that may not be possible by simply depositing SiO2 at the bottom of the trench (or by mere oxidation of the semiconductor material (e.g., SiC) at the trench bottom. In particular, the bottom layer 36 may be, e.g., rectangular or oval in shape, and the bottom layer 36 may be wider than the trench 34 itself, i.e., it may extend laterally into the semiconductor material beyond the width of the trench 34. The side layer 38 of gate oxide may be similarly formed by implantation and thermal oxidation, oxidation of the semiconductor material (without implantation of silicon), or deposition at the side of the trench 34.

In operation, when a voltage, Vgs, is applied between the source 24 and the gate 30, the electric field generated penetrates through the gate oxide layers 36, 38 and creates an inversion layer or channel at the semiconductor-dielectric interface. The inversion layer provides the channel 28 through which electrical current can flow when a voltage, Vds, is applied between the source 24 and drain 26. More specifically, Vgs controls the width of the depletion region at the PN junctions where the charge carriers of the P- and N-type materials diffuse into each other, which "depletes" the available concentrations of majority charge carrier in each material, and thereby controls the current, Id, from the drain 26 to source 24. In the present examples, the thicker bottom gate oxide resists degradation at higher voltages and allows for thinner and narrower shielding which results in a lower Rds(on).

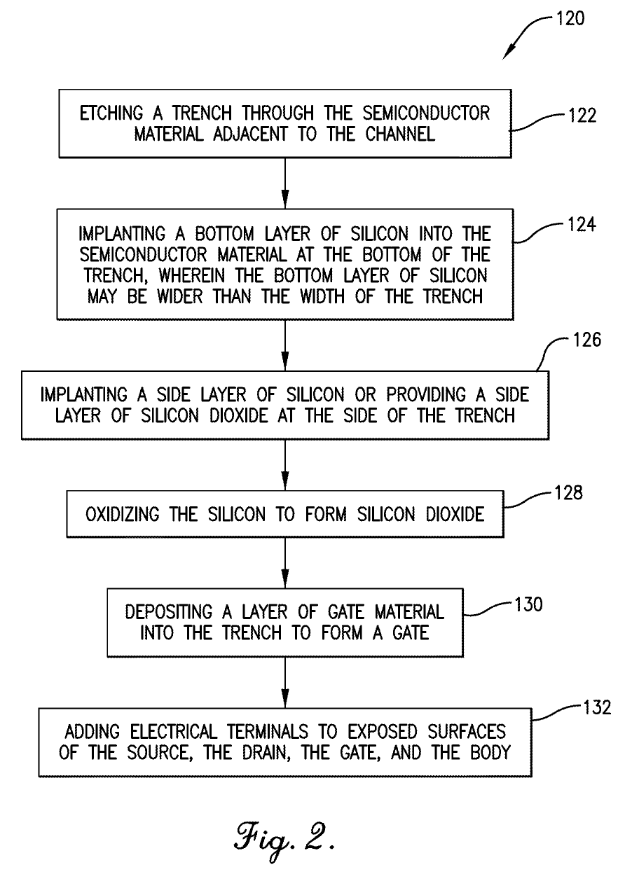

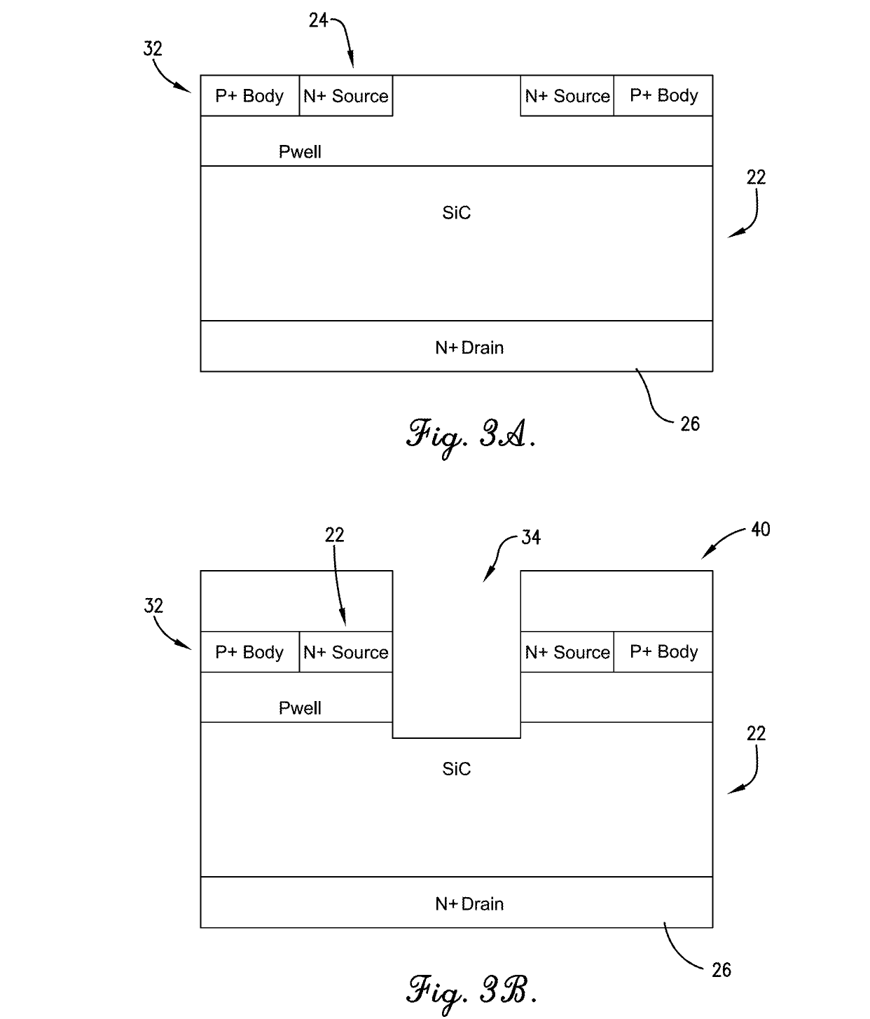

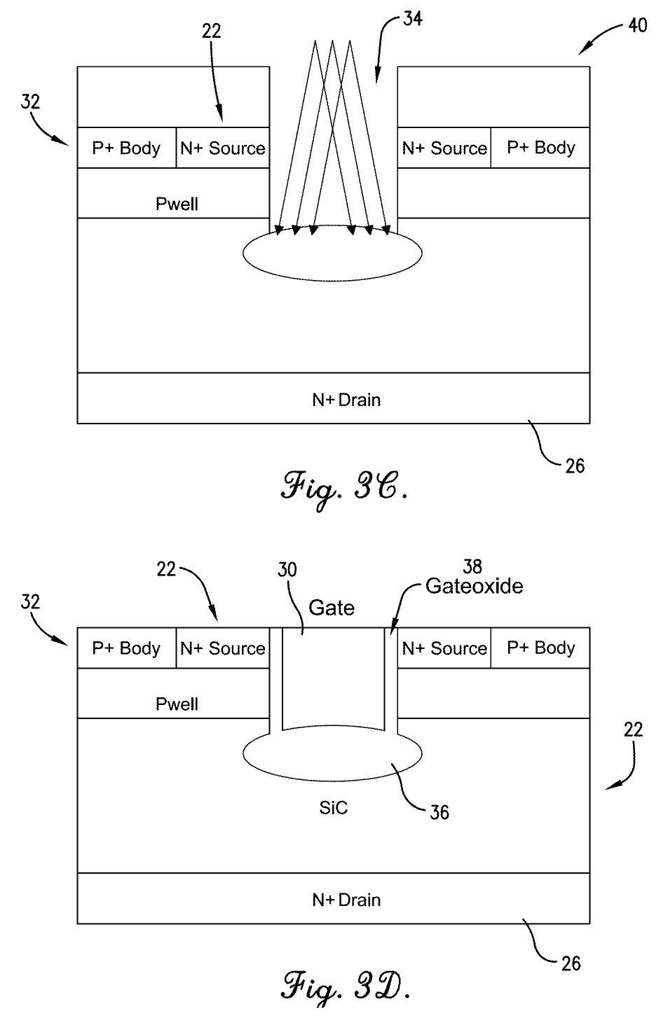

Referring to FIG. 2, an example of a method 120 of manufacturing a trench FET, such as the trench MOSFET 20 described above, with a thicker bottom gate oxide may include the operations set forth below. Referring additionally to FIGS. 3A-D, example results of various operations are shown. The method 120 may begin with a volume of semiconductor material 22 including a first end, a second end, a left side, and a right side, a source 24 located at the first end, a drain 26 located at the second end, a channel 28 extending between the source 24 and the drain 26, and a body 32, as seen in FIG. 3A. As needed or desired, the volume of semiconductor material 22 may include additional structures, such as a well (which may underlie the source 24 and body 32).

A trench 34, the creation of which precedes formation of the gate 30, may be etched into the first end of the volume of semiconductor material 22, as shown in 122 and seen in FIG. 3B. A mask 40 may be used to facilitate the etching process. The trench 34 may have a bottom, a side, and a width. Si may be implanted (using, e.g., an ion implanter) into the semiconductor material at the bottom of the trench 34, as shown in 124 and seen in FIG. 3C. The Si may be implanted so as to be, e.g., rectangular or oval in shape, and may be implanted so as to be wider than the trench 34 itself, i.e., it may laterally extend into the semiconductor material beyond the width of the trench 34. Si may also be implanted into the semiconductor at the side of the trench, as shown in 126 and seen in FIG. 3C, although other aspects contemplate oxidation of the trench side (without a silicon implant) or other forms of deposition of SiO2 along the trench side. If Si implants are initially provided at the bottom and side of the trench 34, the implants may be oxidized (using, e.g., thermal oxidation) to form SiO2, which is a gate oxide, and thereby form a bottom layer 36 of gate oxide and a side layer 38 of gate oxide, as shown in 128 and seen in FIG. 3D.

A layer of polysilicon or other gate material may be deposited into the oxide-lined trench 34 to form the gate 30, as shown in 130 and seen in FIG. 3D. Electrical terminals may be added to exposed surfaces of the source 24, the drain 26, the gate 30, and the body 32, as shown in 132 to facilitate the application of appropriate voltages. Additional processing may occur as desired.

Although described herein with regard or in relation to one or more particular kinds of electronic devices (e.g., junction field-effect transistor, metal oxide semiconductor field-effect transistor), the technology may be more broadly applicable to one or more other kinds of electronic devices as well. Further, one with ordinary skill in the art will recognize that the technology described herein may, when applicable, be implemented in enhancement mode or depletion mode. Additionally, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum dioxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10^18 and 1x10^22; doping concentrations for channel and threshold forming implants may be approximately between 10^16 and 10^17; doping concentrations for shielding implants may be approximately between 10^17 and 10^19; and doping concentrations for conductivity improvement implants (e.g., N- doping in the junction field-effect transistor neck region of a metal oxide semiconductor field-effect transistor) may be approximately between 10^16 and 10^17. Relatedly, a structure or region may contain two or more different doping doses. For example, one with ordinary skill in the art will recognize that some P-wells may contain a lower dose P-well portion and a higher dose unclamped inductive switching portion.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A trench metal-oxide semiconductor field-effect transistor comprising:
a volume of semiconductor material including a first end and a second end;
a source located at the first end of the volume of semiconductor material;
a drain;
a trench extending into the volume semiconductor material from the first end thereof,
the trench being adjacent to the source and including a trench bottom, a trench side extending between the trench bottom and the first end of the volume of semiconductor material, and trench a width; and
a gate oxide located within the trench,
the gate oxide including a bottom layer that is adjacent the trench bottom and presents a bottom oxide layer average thickness,
the gate oxide including a side layer that extends along the trench side and presents a side oxide layer average thickness,
the bottom oxide layer average thickness being greater than the side oxide layer average thickness.

2. The metal-oxide semiconductor field-effect transistor of claim 1,
the bottom layer of gate oxide including silicon dioxide.

3. The trench metal-oxide semiconductor field-effect transistor of claim 1,
the bottom oxide layer average thickness being between one-and-two-tenths (1.2) and five (5) times greater than the side oxide layer average thickness.

44 The metal-oxide semiconductor field-effect transistor of claim 1,
the bottom layer of gate oxide being wider than the trench width.

5. The metal-oxide semiconductor field-effect transistor of claim 1,
the drain being located at the second end of the volume of semiconductor material, such that a vertical channel is defined between the source and the drain.

6. The metal-oxide semiconductor field-effect transistor of claim 1, comprising:
a gate material located within the trench.

7. The metal-oxide semiconductor field-effect transistor of claim 1, comprising:
a well underlying the source,
the well having a lowermost margin spaced closer to the first end of the volume of semiconductor material than the trench bottom.

8. The metal-oxide semiconductor field-effect transistor of claim 7,
the trench including a pair of trench sides,
the side layer of gate oxide extending along each of the trench sides,
the source abutting the side layer of gate oxide extending along each of the trench sides,
the well abutting the side layer of gate oxide extending along each of the trench sides.

9. The metal-oxide semiconductor field-effect transistor of claim 8,
the source including an N+ material,
the well including a P material,
the drain including an N+ material,
a drift portion of the volume of semiconductor material defining at least a portion of a channel extending between the source and drain,
the drift region including N material.

10. A method making a trench field-effect transistor with a thicker bottom gate oxide, the method comprising:
providing a source at a first end of a volume of semiconductor material;
etching a trench into the volume of semiconductor material from the first end thereof, with the trench being adjacent to the source and including a trench bottom, a trench side extending between the trench bottom and the first end of the volume of semiconductor material, and a trench width;
implanting a bottom layer of silicon into the volume of semiconductor material below the trench bottom;
oxidizing the bottom layer of silicon to form a bottom layer of silicon dioxide at the trench bottom;
providing a side layer of silicon dioxide along the trench side; and
depositing a gate material into the trench to form a gate.

11. The method of claim 10,
the step of implanting the bottom layer of silicon including using an ion implanter to implant the silicon.

12. The method of claim 11,
the step of oxidizing the bottom layer of silicon including thermally oxidizing the silicon.

13. The method of claim 12,
the steps of implanting and oxidizing the bottom layer of silicon and providing the side layer of silicon dioxide being performed so that an average thickness of the bottom layer of silicon dioxide is between one-and-two-tenths (1.2) and five (5) times greater than an average thickness of the side layer of silicon dioxide.

14. The method of claim 13,
the step of implanting the bottom layer of silicon being performed so that the bottom layer of silicon dioxide is wider than the trench width.

15. The method of claim 14,
the step of providing the side layer of silicon dioxide including thermally oxidizing the trench side to form the side layer of silicon dioxide.

16. The method of claim 10,
steps of implanting and oxidizing the bottom layer of silicon and providing the side layer of silicon dioxide being performed so that an average thickness of the bottom layer of silicon dioxide is between one-and-two-tenths (1.2) and five (5) times greater than an average thickness of the side layer of silicon dioxide.

17. The method of claim 16,
the step of implanting the bottom layer of silicon being performed so that the bottom layer of silicon dioxide is wider than the trench width.

18. The method of claim 10,
the step of implanting the bottom layer of silicon being performed so that the bottom layer of silicon dioxide is wider than the trench width.

19. The method of claim 10,
the step of providing the side layer of silicon dioxide including thermally oxidizing the trench side to form the side layer of silicon dioxide.
